(19) United States
(12) Patent Application Publication
(10) Pub. No.: US 2008/0148134 A1
(43) Pub. Date: Jun. 19, 2008

(54) DIGITAL DATA DECODING APPARATUS AND DIGITAL DATA DECODING METHOD

(75) Inventor: Norikatsu Chiba, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 11/957,337

(22) Filed: Dec. 14, 2007

(30) Foreign Application Priority Data
Dec. 14, 2006 (JP) 2006-337454

(51) Int. Cl. H03M 13/03; G06F 11/10

(52) U.S. Cl. 714/796; 714/E11.032

(57) ABSTRACT

According to one embodiment, a digital data decoding apparatus has a path computing device adding branch metrics of all paths in an input data series from the path at a state of a current time to the path at a state of a next time to path metrics of the paths corresponding to the branch metrics to obtain the path metrics of all the paths up to the path at the state of the next time and selecting a maximum-likelihood path from among the paths based on the obtained path metrics, and a branch metric calculating device calculating the branch metrics based on a state transition diagram in which a minimum mark/space length is limited to “2” and an equalization characteristic of PR (s, t, 2s, t, s) is provided.

### CROSS-REFERENCE TO RELATED APPLICATIONS

This application is based upon and claims the benefit of priority from Japanese Patent Application No. 2006-337454, filed on Dec. 14, 2006, the entire contents of which are incorporated herein by reference.

### BACKGROUND

1. Field

One embodiment of the invention relates to a digital data decoding apparatus and a digital data decoding method, which are applied to a data reproducing apparatus such as an optical disk apparatus and a hard disk drive performing a signal processing by PRML method.

2. Description of the Related Art

Conventionally, as a recording medium capable of recording and reproducing digital data, there is an optical disk represented by a DVD (digital versatile disk) or a magnetic disk. Of these, as for the optical disk such as a DVD-RAM being a DVD family as an example, a signal recording layer is provided in the recording medium (disk), and when a laser beam having appropriate energy is emitted to the recording layer, the crystal state of the recording layer makes a change, and when the laser beam having appropriate energy is emitted again to the recording layer, a reflected light in accordance with the crystal state of the recording medium can be obtained. It is designed that the digital data is reproduced by detecting this reflected light.

Meanwhile, in recent years, with an aim to realize high-density recoding/reproduction, a technology (PRML technology) of a system called PRML (Partial Response Maximum Likelihood) is adopted in data reproducing apparatuses reproducing digital data recoded in the recording medium such as the optical disk and information recording apparatuses recoding digital data in the recoding medium, and further hard disk drives using a magneto-resistive (MR) head. The PRML technology is a system combining a later-described partial response system and a Viterbi decoding system of which details are disclosed in Japanese Patent Application publication(KOKAI) No. 2001-195830 (Patent document 1) and so forth.

Here, the partial response system (PR) is a system reproducing the digital data by realizing a reproducing circuit without the need of high-frequency component, by compressing necessary signal band by actively using an inter-symbol interference (an interference between reproduced signals caused when adjacent recoded pits enter into a light spot).

Meanwhile, the Viterbi decoding system (ML) is a kind of a so-called maximum likelihood sequence estimation system and is a system reproducing the digital data based on signal amplitude information over a plurality of times by effectively using an inter-symbol interference rule of a reproduced waveform.

Conventionally, the PRML technology is realized by a PLL circuit, an AD converter, an FIR (Finite Impulse Response) filter and a Viterbi decoder.

The Viterbi decoder has a branch metric calculating circuit, an adding/comparing/selecting circuit and a path memory; however, for different constraint lengths, different configurations of those components are required. Accordingly, in order to provide operation modes for a plurality of different constraint lengths with a single data reproducing apparatus, different branch metric calculating circuits, adding/comparing/selecting circuits and path memories are required for each constraint length and this causes an enlarged circuit scale of the Viterbi decoder.

In view of such problems, there has been a conventional technique realizing a plurality of operation modes with a single circuit. The technique provides a mode selecting device for selecting a first operation mode based on a first state transition or a second operation mode based on a second state transition which has a shorter constraint length (less in number of statuses) compared to the first state transition, and operations in a branch metric calculating circuit, an adding/comparing/selecting circuit and a path memory are switched according to a mode selection signal output from the mode selecting device (for example, see Japanese Patent Application publication(KOKAI)No. 2006-14049 (Patent Document 2)).

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram showing an internal configuration of a Viterbi decoder according to an embodiment of the invention;

FIG. 2 is an exemplary block diagram showing an internal configuration of a data reproducing apparatus having the Viterbi decoder incorporated therein in the embodiment;

FIG. 3 is an exemplary diagram showing a configuration of an adding circuit in the embodiment;

FIG. 4 is an exemplary diagram showing a configuration of a comparing and selecting circuit in the embodiment;

FIG. 5 is an exemplary diagram showing a configuration of a decode result determination circuit in the embodiment;

FIG. 6 is an exemplary state transition diagram of a coded signal having a run length limited RLL (1, 10) and an equalization characteristic represented as PR (1, 2, 2, 2, 1) in the embodiment;

FIG. 7 is an exemplary state transition diagram of a coded signal having a run length limited RLL (1, 10) and an equalization characteristic represented as PR (3, 4, 4, 3) in the embodiment;

FIG. 8 is an exemplary state transition diagram of a coded signal having a run length limited RLL (2, 10) and an equalization characteristic represented as PR (3, 4, 4, 3) in the embodiment;

FIG. 9 is an exemplary state transition diagram of a coded signal having a run length limited RLL (1, *) and an equalization characteristic represented as PR (s, t, 2s, t, s) in the embodiment;

FIG. 10 is an exemplary state transition table of a coded signal having a run length limited RLL (1, *) and an equalization characteristic represented as PR (s, t, 2s, t, s) in the embodiment;

FIG. 11 is an exemplary diagram showing a configuration of a branch metric calculating circuit in the embodiment;

FIG. 12 is an exemplary trellis diagram before a line modification to adapt to PR (3, 4, 4, 3), showing overlaid trellis diagrams of PR (1, 2, 2, 2, 1) and PR (3, 4, 4, 3) under run length limited RLL (1, 10), in the embodiment;

FIG. 13 is an exemplary a trellis diagram after the line modification for adapting to PR (3, 4, 4, 3), showing overlaid trellis diagrams of PR (1, 2, 2, 2, 1) and PR (3, 4, 4, 3) under run length limited RLL (1, 10), in the embodiment; and

FIG. 14 is an exemplary diagram showing an impulse response waveform of PR (1, 2, 2, 2, 1).

### DETAILED DESCRIPTION

Various embodiments according to the invention will be described hereinafter with reference to the accompanying drawings. In general, according to one embodiment of the invention, a digital data decoding apparatus has a path computing device adding branch metrics of all paths in an input data series from the path at a state of a current time to the path at a state of a next time to path metrics of the paths corresponding to the branch metrics to obtain the path metrics of all the paths up to the path at the state of the next time and selecting a maximum-likelihood path from among the paths based on the obtained path metrics, and a branch metric calculating device calculating the branch metrics based on a state transition diagram in which a minimum mark/space length is limited to “2” and an equalization characteristic of PR (s, t, 2s, t, s) is provided.

Further, a digital data decoding apparatus has a path computing device adding branch metrics of all paths in an input data series from the path at a state of a current time to the path at a state of a next time to path metrics of the paths corresponding to the branch metrics to obtain the path metrics of all the paths up to the path at the state of the next time and selecting a maximum-likelihood path from among the paths based on the obtained path metrics, and a branch metric calculating device calculating the branch metrics based on a trellis diagram in which a minimum mark/space length is limited to “2” and equalization characteristics of both PR (s, t, 2s, t, s) and PR (s, t, t, s) are provided.

A digital data decoding method has steps of adding branch metrics of all paths in an input data series from the path at a state of a current time to the path at a state of a next time to path metrics of the paths corresponding to the branch metrics to obtain the path metrics of all the paths up to the path at the state of the next time, and selecting a maximum-likelihood path from among the paths based on the obtained path metrics, and calculating the branch metrics based on a state transition diagram in which a minimum mark/space length is limited to “2” and an equalization characteristic of PR (s, t, 2s, t, s) is provided.

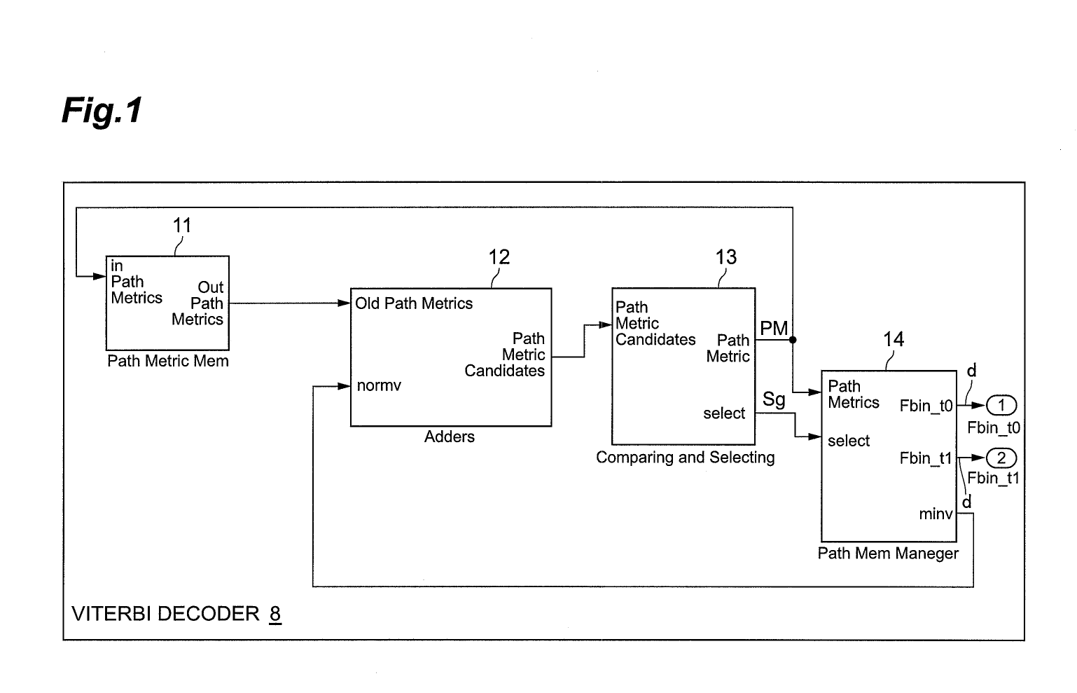

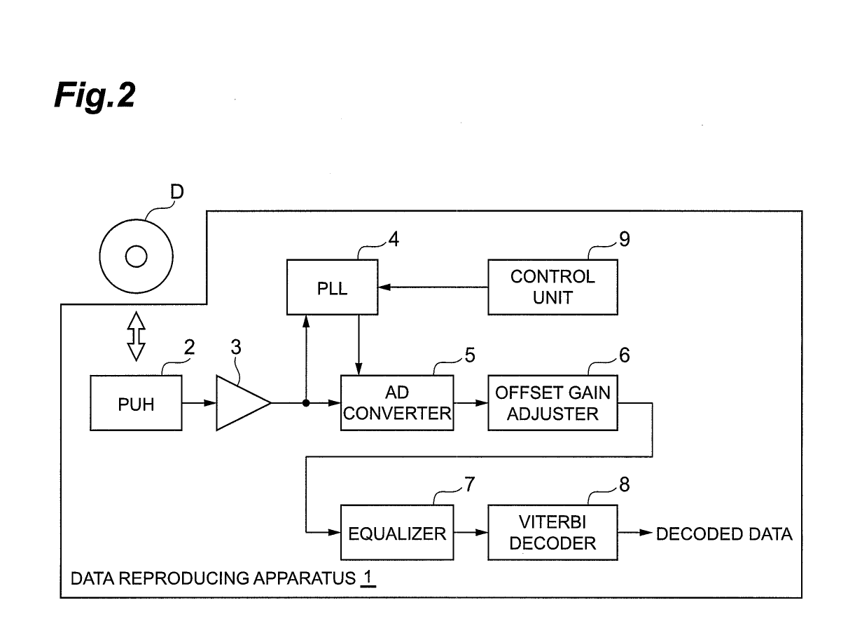

FIG. 1 is a block diagram showing a configuration of a Viterbi decoder 8 as a digital data decoding apparatus according to a first embodiment of the present invention, and FIG. 2 is a block diagram showing a configuration of a data reproducing apparatus 1. Since the Viterbi decoder 8 is installed in the data reproducing apparatus 1 shown in FIG. 2, the data reproducing apparatus 1 will then be described.

The data reproducing apparatus 1 uses an optical disk D as a recoding medium as shown in FIG. 2. The data reproducing apparatus 1 is a disk reproducing apparatus capable of reproducing digital data recorded in the optical disk D and reproduces digital data in compliant with an optical disk standard (for example, an HD DVD or a DVD).

The data reproducing apparatus 1 includes a PUH (pick up head) 2 provided with an optical pickup and the like, a preamplifier 3 and a PLL circuit 4. The data reproducing apparatus 1 also includes an AD converter 5, an offset gain adjuster 6, an adaptive equalizer 7 and the Viterbi decoder 8.

The PUH 2 emits an appropriate laser beam to the optical disk D to detect a light reflected from the optical disk D and outputs a weak analog reproduced signal to the preamplifier 3. The preamplifier 3 performs a processing such as amplification and the like with respect to the analog reproduced signal output from the PUH 2 and, after the signal reaches to a sufficient signal level, outputs the signal to the AD converter 5.

The PLL circuit 4 inputs the analog reproduced signal and generates a reproduction clock synchronized with a clock component of the analog reproduced signal, and then outputs the reproduction clock to the AD converter 5.

The AD converter 5 samples the input analog reproduced signals in accordance with the timings of the reproduction clock and converts the analog reproduced signals into a digital signal series.

The offset gain adjuster 6 performs an offset adjustment and a gain adjustment with respect to the digital signal series output from the AD converter 5, and outputs to the adaptive equalizer 7.

The adaptive equalizer 7 performs a waveform equalization with respect to the digital signal series output from the offset gain adjuster 6 in accordance with the PR characteristic to be adopted and outputs the waveform equalized data to the Viterbi decoder 8. The adaptive equalizer 7 uses an FIR filter. The FIR filter performs the waveform equalization with respect to the digital signal series using a predetermined filter coefficient and outputs to the Viterbi decoder 8. A control unit 9 will be described later.

The description will be given of the configuration of the Viterbi decoder 8. The Viterbi decoder 8 includes a path metric memory 11, an adding circuit 12, a comparing and selecting circuit 13 and a decode result determination circuit 14, as shown in FIG. 1.

The Viterbi decoder 8 performs adding a branch metric about a path metric, comparing and selecting about the path metrics by adding circuit 12 and the comparing and selecting circuit 13, as will be described below. Those circuits compose a path computing device.

The Viterbi decoder 8 calculates the metrics of the digital signal series (input data series) input from the adaptive equalizer 7, that are at the state of the respective sample points, and then, stores a path having the smallest metric among the F input data series as a most likely path (referred to as a maximum-likelihood path or a survival path). The Viterbi decoder 8 decodes the digital data by repeating this operation at each time. Here, the metric indicates an additional value at each state of the branch metric and the branch metric indicates a stochastic length of the each path.

The path metric memory 11 stores the path metric PM of the path selected by the comparing and selecting circuit 13 and the path metric PM is used as a path metric of next time.

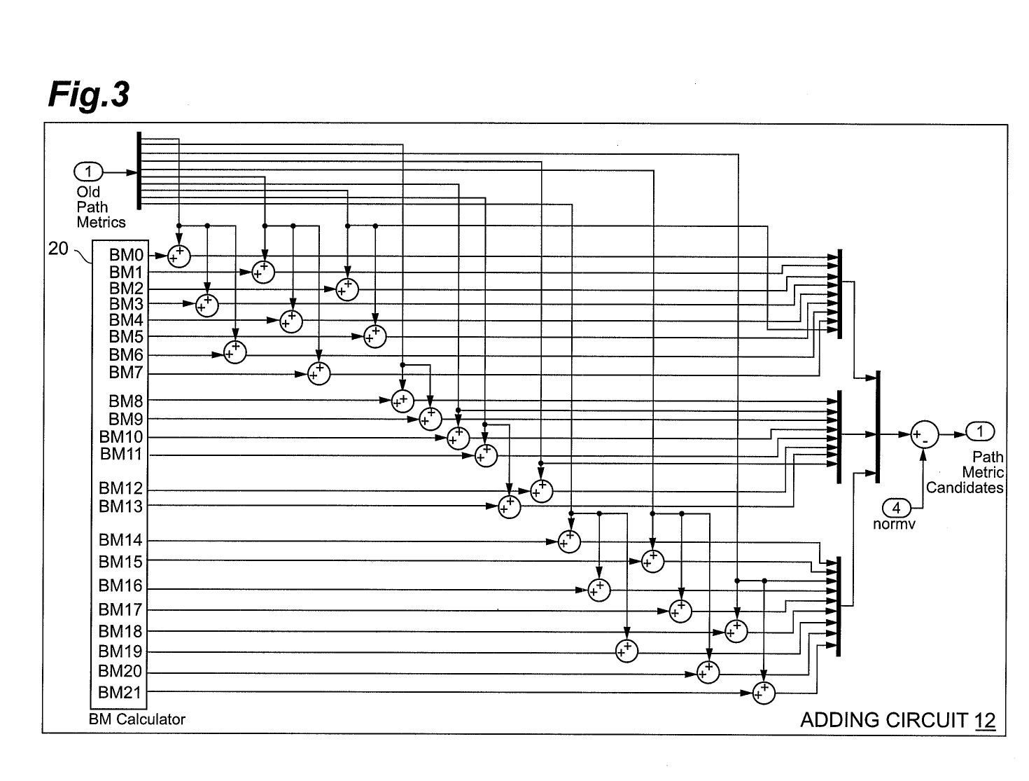

The adding circuit 12 has a later-described branch metric calculating circuit 20, as shown in FIG. 3. The adding circuit 12 adds the branch metrics (BM 0 to BM 21) of all the paths calculated by the branch metric calculating circuit 20 to the path metrics of the paths corresponding to the branch metrics, respectively, to thereby obtain the path metrics of all the paths up to the path at the state of the next time (the calculating of the branch metrics by the branch metric calculating circuit 20 is also called a “branch metric calculation”).

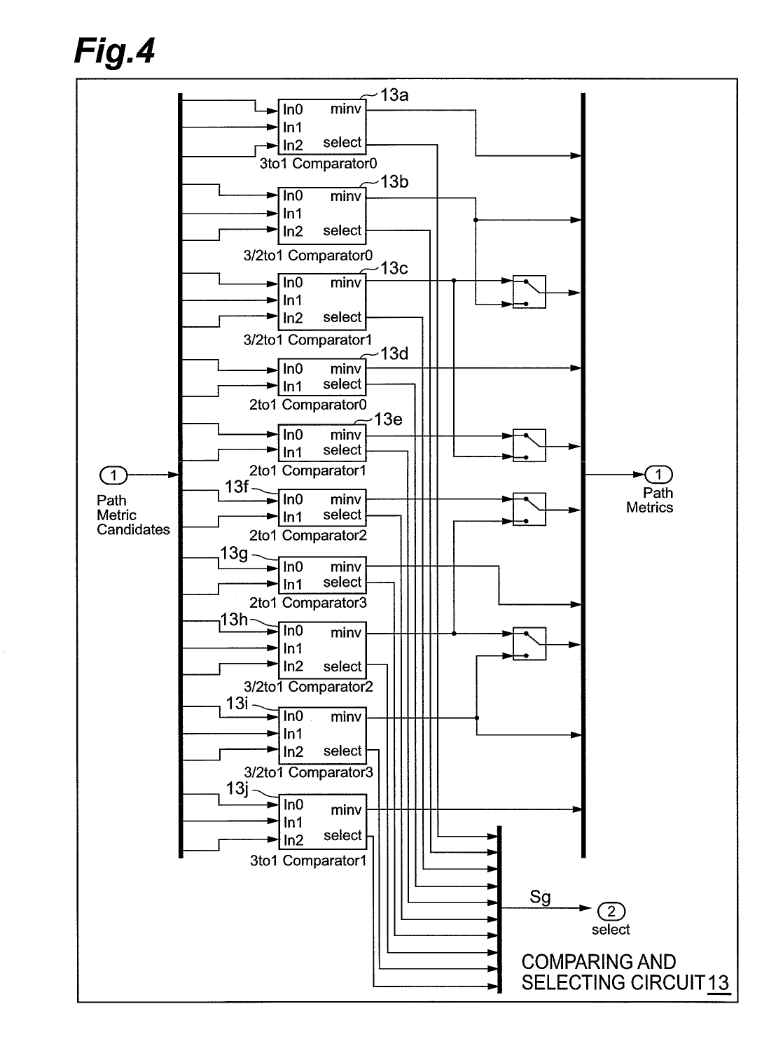

As shown in FIG. 4, the comparing and selecting circuit 13 has comparators 13a to 13j. In the comparing and selecting circuit 13, the comparator 13a to 13j compare the path metrics PM of each path obtained by the adding circuit 12 to obtain a path metric having the smallest value. Further, in the comparing and selecting circuit 13, the comparators 13a to 13j perform a path selection for selecting a path corresponding to the path metric PM having the smallest value as a most likely path (maximum-likelihood path) and output a selection signal sg indicating the selected path to the decode result determination circuit 14.

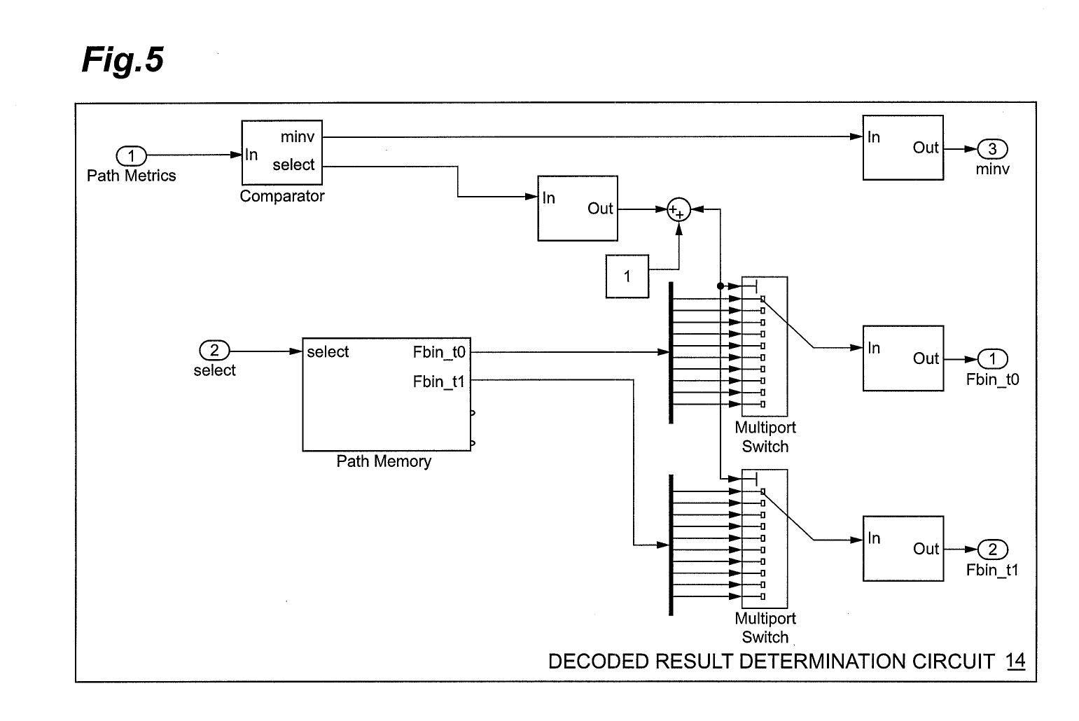

The decode result determination circuit 14 has a circuit configuration as shown in FIG. 5. The decode result determination circuit 14 inputs the selection signal sg from the comparing and selecting circuit 13 and determines a final survival path to store the determined path. The decode result determination circuit 14 decodes the digital data by tracking back the survival path in use of the selection signal sg output from the comparing and selecting circuit 13 and outputs decoded data d. Further, the decode result determination circuit 14 outputs a normalization value to prevent a saturation of the path metrics.

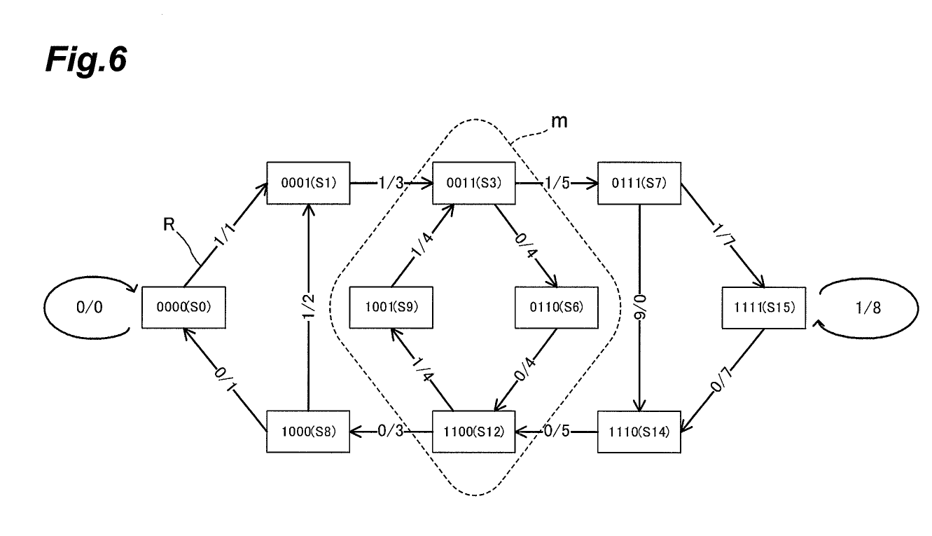

A state transition diagram of the Viterbi decoder 8 will be described. FIG. 6 shows a state transition diagram of a coded signal having a run length limited RLL (1, 10) and an equalization characteristic represented as PR (1, 2, 2, 2, 1), prescribed by a standard of HD DVD.

In the state transition diagram, when the constraint length is 5 and the run length limited is RLL (1, 10), there are ten possible states: S(0), S(1), S(3), S(6), S(7), S(8), S(9), S(12), S(14) and S(15).

Further, in the state transition diagram, the arrows indicating transitions of each state are shown. With each arrow, numbers in form of P/Q are provided. The left number P indicates an input value and the right number Q indicates an output value. For example, with the arrow R indicating a transition from the state S(0) to the state S(1), a numbers of “1/1” are given. This means that its input value is “1” and output value is “1”.

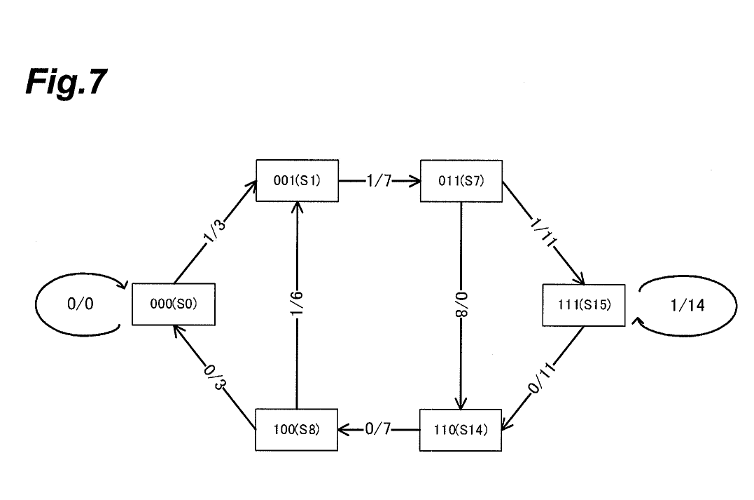

When the equalization characteristic (PR class) is changed to PR (3, 4, 4, 3) with the same run length limited (RLL (1, 10)), the state transition diagram changes as shown in FIG. 7. In this state transition diagram, there are six possible states: S(0), S(1), S(7), S(8), S(14) and S(15).

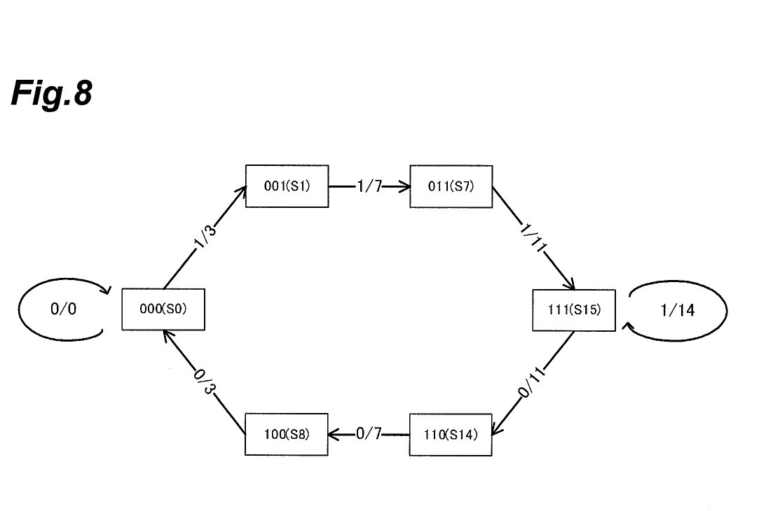

Further, when the equalization characteristic represented as PR (3, 4, 4, 3) is changed to run length limited RLL (2, 10), which is prescribed by a standard of DVD, the state transition diagram changes as shown in FIG. 8. In this state transition diagram, there are six states: S(0), S(1), S(7), S(8), S(14) and S(15); however, a transition from the state S(8) to the state S(1) and a transition from the state S(7) to the state S(14) are not provided.

As described above, the state transition diagram for a DVD and the state transition diagram for an HD DVD are different. The Viterbi decoder 8 decodes a coded signal based on a state transition diagram covering those different state transition diagrams, as described below, in order to decode in both of the DVD and HD DVD within a single circuit.

On the other hand, in order to provide a single state transition diagram covering different state transition diagrams, a branch metric of a branch in one of the different state transition diagrams needs to be calculated in addition to a branch metrics of a branch common to the different state transition diagrams. Accordingly, more multipliers and adders for calculating the branch metrics are required.

For this, the Viterbi decoder 8 is configured to perform branch metric calculation with fewer multipliers and adders by setting later described addition constants A to D and multiplication constants a to g. Here, the Viterbi decoder 8 is capable of operating according to a half-rate input. The details will be described later.

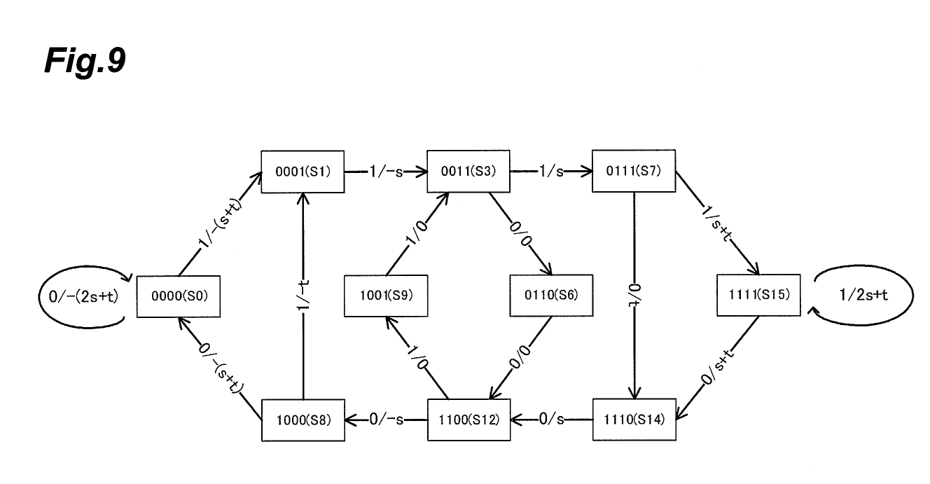

Firstly, regarding a coded signal of an HD DVD in which a minimum mark/space length is limited to “2” (run length limited RLL (1, *); the * is an integral number), the equalization characteristic is extended to PR (s, t, 2s, t, s) (the “s” and “t” are positive integral numbers). As considering, for example, a symmetry property of values, the state transition diagram in this case is formed as shown in FIG. 9.

In this state transition diagram, there exist ten possible states: S(0), S(1), S(3), S(6), S(7), S(8), S(9), S(12), S(14) and S(15), and the arrows indicating transitions of each states are shown. With each arrow, a number and variable are provided in form of P/Q. The left number (P) indicates an input value and the right variable (Q) indicates an output value. The variables shown by each arrow can be “0”, or be determined by s or t. For example, “0/−(2s+t)” indicates that its input is “0” and output is “−(2s+t).”

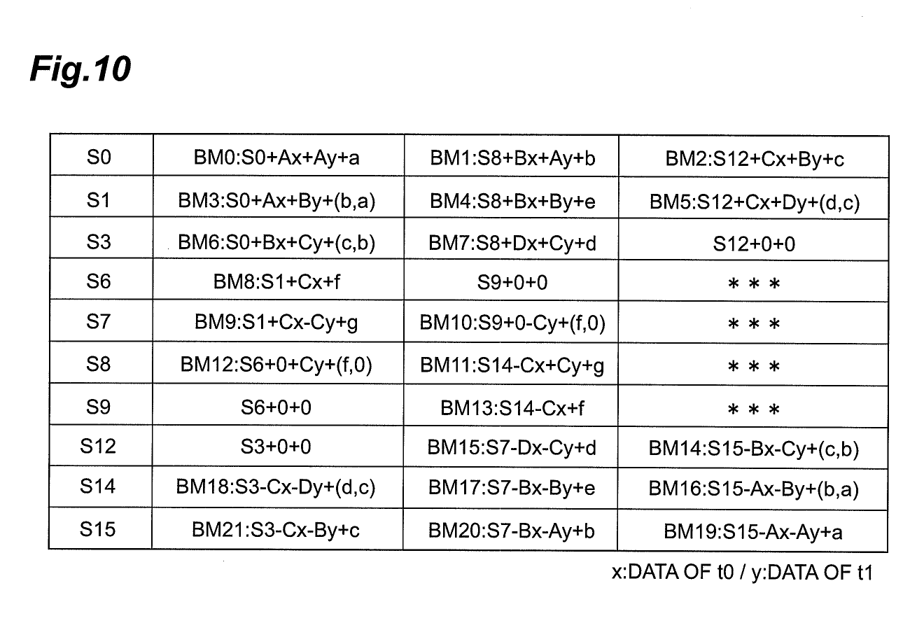

When a branch metric of a coded signal is calculated based on the state transition diagram shown in FIG. 9, the branch metric can be obtained with a calculation formulas shown in a state transition table in FIG. 10. The A, B, C and D shown in FIG. 10 are multiplication constants represented according to the following Equations 1 and 2. The right side of each equation is a multiplication constant and defined by s or t composing PR (s, t, 2s, t, s) based on the equalization characteristic of the PR (s, t, 2s, t, s).

A=2(2s+t), B=2(s+t) Equation 1

C=2s, D=2t Equation 2

Further, the a, b, c, d, e, f and g are addition constants represented according to Equations 3 to 7. The right side of each equation is addition constant and defined by or t.

a=(2s+t)²+(2s+t)² Equation 3

b=(s+t)²+(2s+t)² Equation 4

c=s²+(s+t)², d=s²+t² Equation 5

e=(s+t)²+(s+t)² Equation 6

f=(s+t)²+s², g=s²+s² Equation 7

Further, the x and y shown in FIG. 10 are data of coded signal to be input to the Viterbi decoder 8, which indicate temporally-subsequent two pieces of data. For example, when “t=1” and “t=2” are temporally-subsequent pieces of data, x represents “t=1” and y represents “t=2.” Further, in FIG. 10, regarding the items shown in form of “(p, q),” the “p” or “q” is to be selected depending on cases.

Collecting the branch metric calculation formulas as shown in FIG. 10, the multiplication constants required to branch metric calculation can be limited to four constants: A, B, C and D, and constant terms to be added (addition constants) can be limited to seven constants: a, b, c, d, e, f and g.

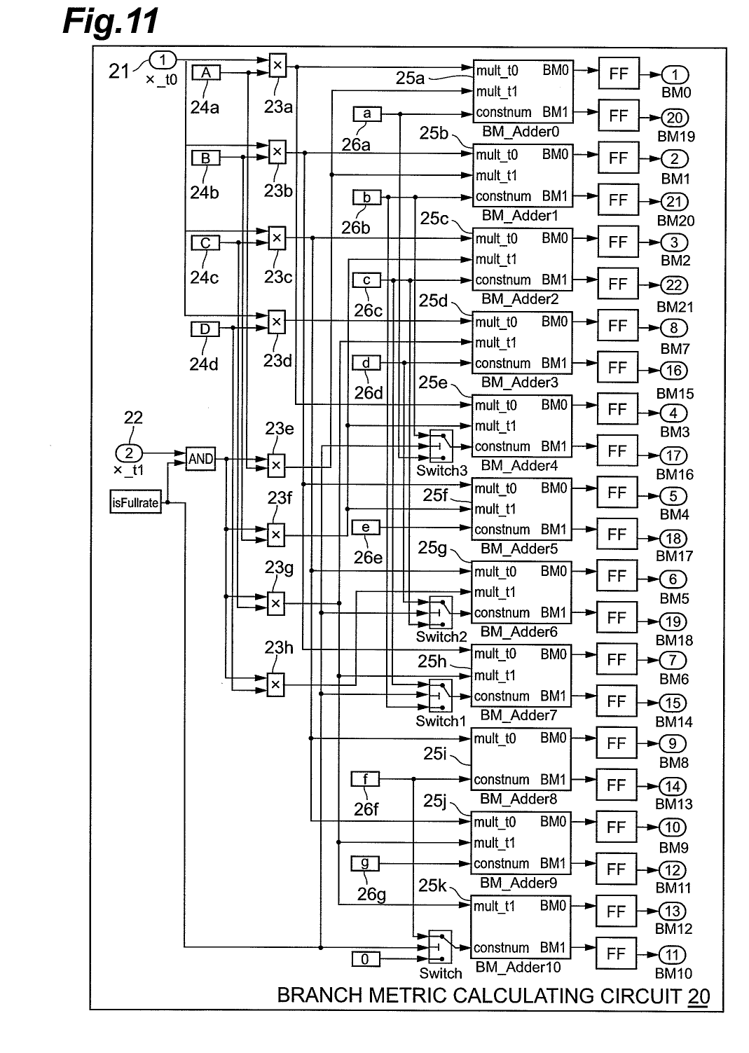

The branch metric calculating circuit 20 performs branch metric calculation based on FIG. 10. The configuration of the branch metric calculating circuit 20 is shown in FIG. 11.

The branch metric calculating circuit 20 includes a couple of input parts 21, 22. To the input parts 21, 22, temporally subsequent data are input, respectively. For example, data of “t=1” is input to the input part 21 and data of “t=2” is input to the input part 22.

The branch metric calculating circuit 20 has eight multipliers 23a, 23b, 23c, 23d, 23e, 23f, 23g, 23h and four registers 24a, 24b, 24c, 24d. The branch metric calculating circuit 20 also has eleven BM adders 25a, 25b, 25c, 25d, 25e, 25f, 25g, 25h, 25i, 25j, 25k and seven registers 26a, 26b, 26c, 26d, 26e, 26f, 26g.

Data is input to the multipliers 23a, 23b, 23c, 23d from the input part 21 and multiplied by multiplication constants which are respectively set to the registers 24a, 24b, 24c, 24d. The above described four multiplication constants A, B, C and D are respectively set to the registers 24a, 24b, 24c, 24d.

Data is input to the multipliers 23e, 23f, 23g, 23h from the input part 22. Multipliers 23e, 23f, 23g, 23h perform multiplication using multiplication constants which are respectively set to the registers 24a, 24b, 24c, 24d.

The BM adders 25a to 25k add with one of addition constants set to the registers 26a to 26h to calculate a branch metric.

The BM adders 25a to 25h have a couple of three-term adders (not shown) to perform adding using an addition constant which is set to one of the registers 26a to 26e.

The BM adder 25i has a couple of two-term adders to perform adding using an addition constant which is set to the register 26f.

The BM adder 25j has a couple of three-term adders to perform adding using an addition constant which is set to the register 26g.

The BM adder 25k has a couple of two-term adders to perform adding using an addition constant which is set to the register 26f.

With the branch metric calculating circuit 20 having the above described configuration, the Viterbi decoder 8 can decode a coded signal of a run length limited RLL (1, *) having an equalization characteristic of PR (s, t, 2s, t, s).

The state transition diagram of the coded signal having the equalization characteristic of PR (s, t, 2s, t, s) is as shown in FIG. 9 and this covers all state transition diagrams shown in FIGS. 6 to 8. Thus, the state transition diagram shown in FIG. 9 covers the state transition diagrams of both HD DVDs and DVDs. Accordingly, the Viterbi decoder 8 can decode data of both HD DVDs and DVDs with a single circuit.

Further, when decoding data of an HD DVD and a DVD, the Viterbi decoder 8 is not required to select operation modes for the HD DVD and DVD.

Further, since the multiplication constants are limited to four constants and the addition constants are limited to seven constants in the branch metric calculating circuit 20, as described above, the branch metric calculating circuit 20 can be composed of a few multipliers, adders and fixed value storing registers.

On the other hand, the branch metric calculating circuit 20 can decode coded signal having the equalization characteristic represented as PR (s, t, t, s) as follows, focusing on the approximation of the trellis diagrams of PR (s, t, 2s, t, s) and PR (s, t, t, s). This will be explained with an example of trellis diagrams of, for example, PR (1, 2, 2, 2, 1) and PR (3, 4, 4, 3).

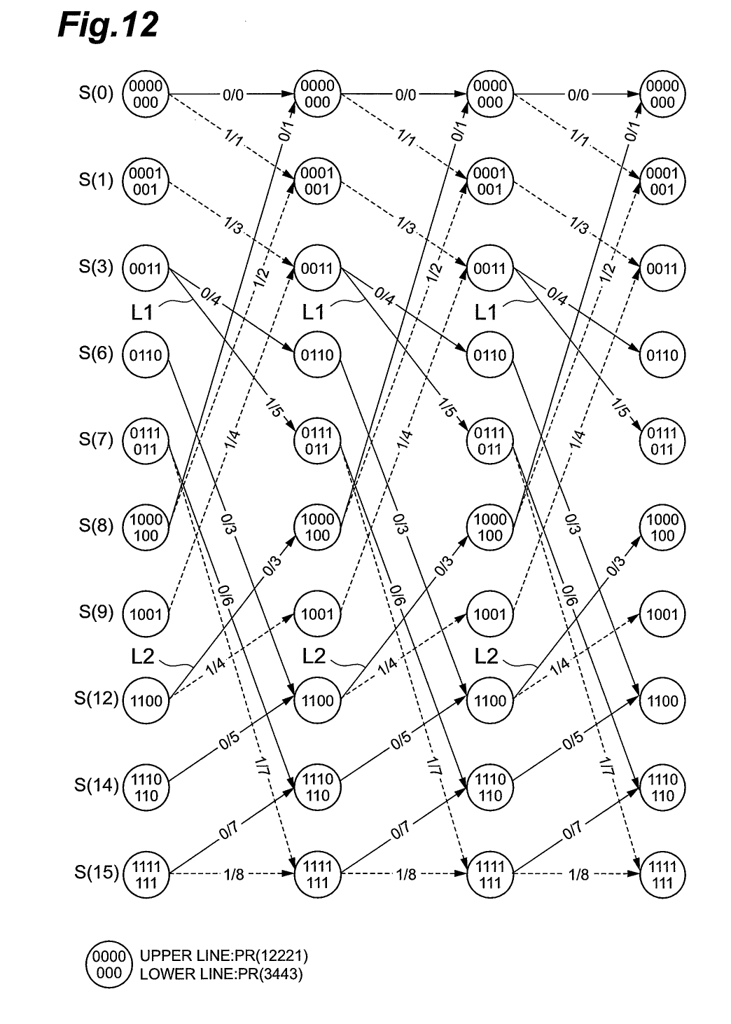

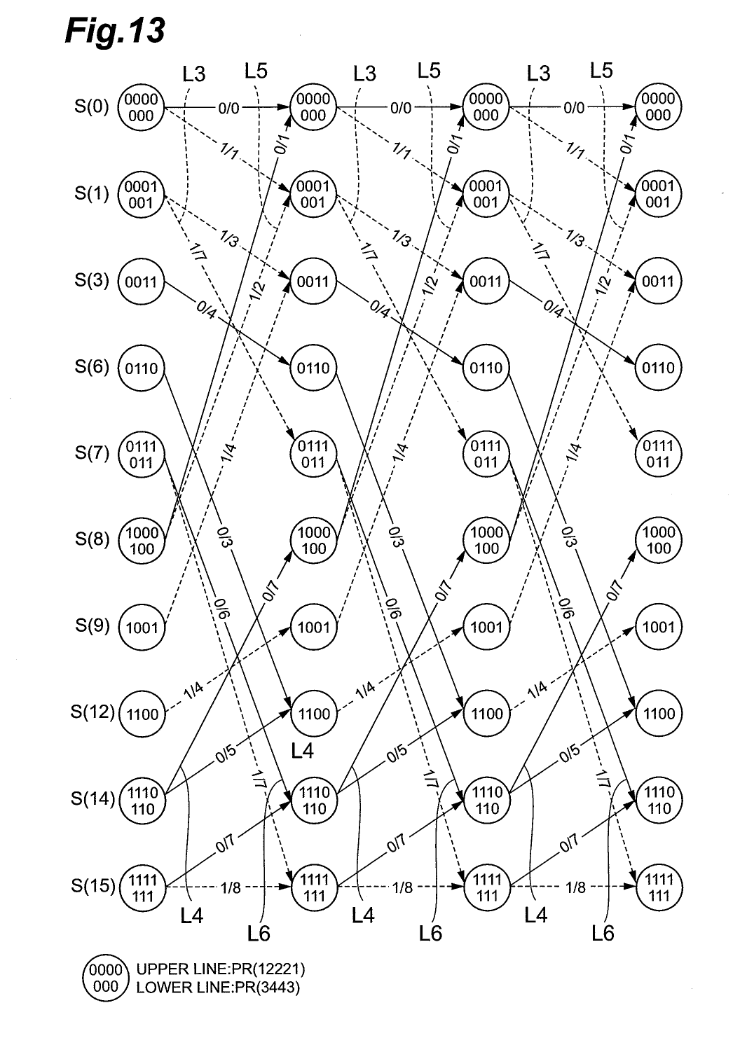

FIG. 12 shows a trellis diagram before a line modification for adapting to PR (3, 4, 4, 3), showing overlaid trellis diagrams of PR (1, 2, 2, 2, 1) and PR (3, 4, 4, 3) under run length limited RLL (1, 10). Further, FIG. 13 shows a trellis diagram after the line modification for adapting to PR (3, 4, 4, 3), showing overlaid trellis diagrams of PR (1, 2, 2, 2, 1) and PR (3, 4, 4, 3).

Since the trellis diagrams correspond to the state transition diagrams, FIGS. 6 and 7 will hereunder be weighed. From a condition with ten states shown in FIG. 6, the four states S(3), S(6), S(9) and S(12) within the area m defined by the dotted line are removed and the numbers representing transitions of each state are modified. With this, the state transition diagram of FIG. 6 changes to the state transition diagram of FIG. 7.

With this prospect, when the lines L1 and L2 are removed in FIG. 12 and, alternatively, lines L3 and L4 are added, the trellis diagram of FIG. 13 can be obtained. The trellis diagram shown in FIG. 13 is adaptive to both of PR (1, 2, 2, 2, 1) and PR (3, 4, 4, 3).

Further, when the lines L3 and L4 are removed from the trellis diagram of FIG. 13, the trellis diagram becomes adaptive to PR (3, 4, 4, 3) of run length limited RLL (2, 10). It is noted that such a relation is available between PR (s, t, 2s, t, s) and PR (s, t, t, s).

Based on the trellis diagram of FIG. 13, the multiplication constants and addition constants are set by the following Equations 10 to 12.

A=2(s+t), B=2t, C=0, D=2(t−s) Equation 10

a=(s+t)²+(s+t)², b=t²+(s+t)² Equation 11

c=t², d=(t−s)², e=t²+t², f=0, g=0 Equation 12

As described above, the Viterbi decoder 8 can decode the coded signal of the equalization characteristic of PR (s, t, t, s) in addition to the coded signal of the equalization characteristic of PR (s, t, 2s, t, s).

The above described Viterbi decoder 8 assumes operate in accordance with a full-rate input. The full-rate input is an input of a digital signal series obtained by sampling by the AD converter 5 in accordance with a reproduction clock synchronized with a channel bit rate. The Viterbi decoder 8 can also operate in accordance with a half-rate input in addition to such a full-rate input. The half-rate input is an input of a digital signal series obtained by sampling by the AD converter 5 in accordance with a reproduction clock synchronized with a half-length frequency of the channel bit rate (hereinafter, referred to as “half-rate clock”).

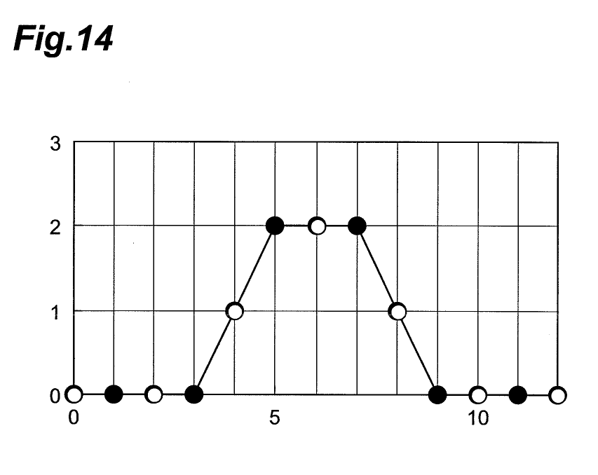

Here, FIG. 14 is a diagram showing an impulse response waveform of PR (1, 2, 2, 2, 1). When the AD converter 5 takes samples in accordance with the reproduction clock synchronized with the channel bit rate, sample data (the data at the respective times composing the input data series) of both points represented by white circles (◯) and black circles () in FIG. 15 are obtained. However, when the AD converter 5 takes samples in accordance with the half-rate clock, only the sample data at the points represented by the white circles (◯) or the black circles () are obtained and input to the branch metric calculating circuit 20.

When the Viterbi decoder 8 operates in accordance with the full-rate input, data is input to the input part 21 and the input part 22 of the branch metric calculating circuit 20; however, when operating in accordance with the half-rate input, data is input to the input part 21 of the branch metric calculating circuit 20 but not to the input part 22. In such case, also, since the branch metric calculating circuit 20 calculates a branch metric for the data input from the input part 21, the Viterbi decoder 8 can operate in accordance with the half-rate input.

Further, the Viterbi decoder 8 operates in accordance with a half-rate clock in addition to the reproduction clock synchronized with the channel bit frequency. In other words, the Viterbi decoder 8 is configured to operate when data is input to both of the input part 21 and input part 22 (input at both of the white circles (◯) and black circles () in FIG. 14) and even when the frequency is half.

Then, when the AD converter 5 take samples in accordance with the half-rate clock, the number of data input to the Viterbi decoder 8 can be reduced in half and the operating frequency of the Viterbi decoder 8 itself can also be made half. Accordingly, in the data reproducing apparatus 1, operating frequencies of the AD converter 5, adaptive equalizer 7 and the like provided in a previous stage of the Viterbi decoder 8 can be shortened in half. Therefore, power consumption in the data reproducing apparatus 1 can be reduced.

Then, in the Viterbi decoder 8, the addition constants can be set as follows to operate in accordance with the half-rate input.

In other words, in case of PR (s, t, 2s, t, s), the addition constant can be set based on the following Equations 15 and 16.

a=(2s+t), b=(s+t)², c=s², d=t² Equation 15

e=(s+t)², f=s², g=s² Equation 16

Further, in case of PR (s, t, t, s), the addition constants can be set based on the following Equations 17 and 18.

a=(s+t)², b=t², c=0, d=(t−s)² Equation 17

e=t², f=0, g=0 Equation 18

When a control signal is input to the PLL circuit 4 and the reproduction clock is switched, the operations for the full-rate input and half-rate input can be switched. In this case, as shown in FIG. 1, the control unit 9 can be provided. The control unit 9 composes a switching device.

According to the above descried embodiment, mainly, PR (1, 2, 2, 2, 1) is described as an example of PR (s, t, 2s, t, s) and PR (3, 4, 4, 3) is described as an example of PR (s, t, t, s); however, the Viterbi decoder 8 can decode coded signals of other PR (s, t, 2s, t, s) and PR (s, t, t, s) by modifying the s and t.

The above-described description is to describe an embodiment of the invention and is not intended to limit the apparatus and the method of the invention, allowing various modification examples to be embodied with ease. Further, the apparatus and the method composed by appropriately combining the components, the functions, the characteristics and the steps of method of the respective embodiments are also within the scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital data decoding apparatus comprising:
a path computing device configured to add branch metrics of all paths in an input data series from the path at a state of a current time to the path at a state of a next time to path metrics of the paths corresponding to the branch metrics to obtain the path metrics of all the paths up to the path at the state of the next time and further configured to select a maximum-likelihood path from among the paths based at least in part on the obtained path metrics; and
a branch metric calculating device configured to calculate the branch metrics based at least in part on a state transition diagram in which a minimum mark/space length is limited to “2” and an equalization characteristic of PR (s, t, 2s, t, s) is provided.

2. A digital data decoding apparatus comprising:
a path computing device configured to add branch metrics of all paths in an input data series from the path at a state of a current time to the path at a state of a next time to path metrics of the paths corresponding to the branch metrics to obtain the path metrics of all the paths up to the path at the state of the next time and further configured to select a maximum-likelihood path from among the paths based at least in part on the obtained path metrics; and
a branch metric calculating device configured to calculate the branch metrics based at least in part on a trellis diagram in which a minimum mark/space length is limited to “2” and equalization characteristics of both PR (s, t, 2s, t, s) and PR (s, t, t, s) are provided.

3. The digital data decoding apparatus according to claim 1, wherein the branch metric calculating device is configured to calculate the branch metrics at least in part by multiplying and adding with a multiplication constant and an addition constant based on the equalization characteristic of the PR (s, t, 2s, t, s).

4. The digital data decoding apparatus according to claim 2, wherein the branch metric calculating device is configured to calculate the branch metrics at least in part by multiplying and adding with a multiplication constant and an addition constant based on the equalization characteristics of both the PR (s, t, 2s, t, s) and the PR (s, t, t, s).

5. The digital data decoding apparatus according to claim 3, wherein the multiplication constant comprises four constants of A, B, C and D defined by the following equations:
A=2(2s+t), B=2(s+t), C=2s, and D=2t.

6. The digital data decoding apparatus according to claim 3, wherein the addition constant comprises seven constants a, b, c, d, e, f and g defined by the following equations:
a=(2s+t)²+(2s+t)², b=(s+t)²+(2s+t)²
c=s²+(s+t)², d=s²+t²
e=(s+t)²+(s+t)², f=(s+t)²+s²,
and
g=s²+s².

7. The digital data decoding apparatus according to claim 5, wherein the addition constant comprises seven constants a, b, c, d, e, f and g defined by the following equations:
a=(2s+t)²(2s+t)², b=(s+t)²+(2s+t)²
c=s²+(s+t)², d=s²+t²
e=(s+t)²+(s+t)², f=(s+t)²+s²,
and
g=s²+s².

8. The digital data decoding apparatus according to claim 4, wherein the multiplication constant comprises four constants A, B, C and D defined by the following equations:
A=2(2s+t), B=2t, C=0, and D=2(t−s).

9. The digital data decoding apparatus according to claim 4, wherein the addition constant comprises seven constants a, b, c, d, e, f and g defined by the following equations:
a=(s+t)²+(s+t)², b=t²+(s+t)²,
c=t², d=(t−s)², e=t²+t², f=0, and g=0.

10. The digital data decoding apparatus according to claim 8, wherein the addition constant comprises seven constants a, b, c, d, e, f and g defined by the following equations:
a=(s+t)²+(s+t)², b=t²+(s+t)²,
c=t², d=(t−s)², e=t²+t², f=0, and g=0.

11. The digital data decoding apparatus according to claim 1, wherein the branch metric calculating device comprises a plurality of input parts to which can be input temporally-consecutive data in coded signals constituting the input data series, and wherein the branch metric calculating device is configured to operate according to a half-rate input for a coded signal input from one of the input parts.

12. The digital data decoding apparatus according to claim 1, wherein the branch metric calculating device is configured to operate in accordance with a half-rate clock synchronized to a half frequency of a channel bit frequency.

13. The digital data decoding apparatus according to claim 11, further comprising a switching device configured to switch a full-rate input for the coded signal input from the plurality of input parts and the half-rate input.

14. The digital data decoding apparatus according to claim 1, further comprising a path metric memory device configured to store the path metric of the maximum-likelihood path selected by the path computing device.

15. A digital data decoding method comprising:
adding branch metrics of all paths in an input data series from the path at a state of a current time to the path at a state of a next time to path metrics of the paths corresponding to the branch metrics to obtain the path metrics of all the paths up to the path at the state of the next time, and selecting a maximum-likelihood path from among the paths based at least in part on the obtained path metrics; and
calculating the branch metrics based at least in part on a state transition diagram in which a minimum mark/space length is limited to “2” and an equalization characteristic of PR (s, t, 2s, t, s) is provided.
